(19) United States
(12) Patent Application Publication
(10) Pub. No.: US 2003/0137365 A1
(43) Pub. Date: Jul. 24, 2003

(54) Surface acoustic wave device and communication apparatus including the same

(76) Inventor: Yuichi Takamine, Kanazawa-shi (JP)

Correspondence Address: KEATING & BENNETT LLP, Suite 312, 10400 Eaton Place, Fairfax, VA, 22030, US

(21) Appl. No.: 10/347,409

(22) Filed: Jan. 21, 2003

(30) Foreign Application Priority Data
Nov. 29, 2002 (JP) 2002-348949
Jan. 21, 2002 (JP) 2002-011661

(51) Int. Cl. H03H 9/64

(52) U.S. Cl. 333/133; 333/193; 333/195

(57) ABSTRACT

A surface acoustic wave device includes two surface acoustic wave filters. Each of the filters includes an odd number of at least three IDTs arranged in the propagation direction of a surface acoustic wave on a piezoelectric substrate. The phase of an output signal relative to an input signal in one of the two filters is inverted by 180° with respect to the phase in the other filter such that an unbalanced-to-balanced transformer function is obtained. When the number of the IDTs is indicated by N, IDTs having a number equal to (N−1)/2+1 are connected to an unbalanced signal terminal and IDTs having a number equal to (N−1)/2 are connected to a balanced signal terminal in each filter. The total number of electrode fingers of the IDTs in each filter is at least 71. When the total number of electrode fingers of the IDTs connected to the unbalanced signal terminal is indicated by N1 and the total number of electrode fingers of the IDT connected to the balanced signal terminal is indicated by N2 in each filter, an expression N1>N2 is satisfied.

### BACKGROUND OF THE INVENTION

1. Field of the Invention

The present invention relates to a surface acoustic wave device having an unbalanced-to-balanced transformer function, and also relates to a communication apparatus including an unbalanced-to-balanced transformer function.

2. Description of the Related Art

Recently, technologies for miniaturization and weight reduction of communication apparatuses, such as mobile phones, have been developed. In order to achieve miniaturization and weight reduction, the number of components and the size of each component have been reduced. In addition, components having a plurality of functions have been developed.

Under such circumstances, surface acoustic wave devices which are used in the RF stage of mobile phones and which have an unbalanced-to-balanced transformer function or a so-called balun function have been widely studied and have become common in global systems for mobile communications (GSM) in recent years. Some patent applications relating to a surface acoustic wave device having such an unbalanced-to-balanced transformer function have been filed.

FIG. 21 shows the configuration of a known surface acoustic wave device. The surface acoustic wave device includes two longitudinally-coupled resonator type surface acoustic wave filters. In this surface acoustic wave device, the impedance of a balanced signal terminal is four times the impedance of an unbalanced signal terminal.

As shown in FIG. 21, the surface acoustic wave device includes two longitudinally-coupled resonator type surface acoustic wave filters 101 and 102. The surface acoustic wave filter 101 includes three interdigital transducers (IDTs) 103, 104, and 105. Also, reflectors 106 and 107 are arranged such that they sandwich the IDTs 103 to 105. Likewise, the surface acoustic wave filter 102 includes three IDTs 108, 109, and 110. Also, reflectors 111 and 112 are arranged such that they sandwich the IDTs 108 to 110. The IDTs 103 to 105 and the IDTs 108 to 110 are arranged in a line extending along the propagation direction of a surface acoustic wave.

In the surface acoustic wave device, the direction of the IDTs 108 and 110 of the surface acoustic wave filter 102 is inverted in the interdigital width direction with respect to the IDTs 103 and 105 of the surface acoustic wave filter 101. Accordingly, the phase of an output signal to an input signal in the surface acoustic wave filter 102 is inverted by about 180° with respect to the phase in the surface acoustic wave filter 101.

Also, the IDTs 104 and 109 are connected to a signal terminal 113. The IDTs 103 and 105 are connected to a signal terminal 114. The IDTs 108 and 110 are connected to a signal terminal 115.

The signal terminal 113 defines an unbalanced signal terminal and the signal terminals 114 and 115 define balanced signal terminals such that an unbalanced-to-balanced transformer function is produced. In this surface acoustic wave device, the impedance of the balanced signal terminal is four times the impedance of the unbalanced signal terminal.

However, when a surface acoustic wave device having a wide passband and a high-frequency, such as a DCS filter, is produced with the above-described configuration, a preferable voltage standing wave ratio (VSWR) and deviation in the passband cannot be obtained. The reasons for this are as follows: the effect of parasitic capacitance generated on a piezoelectric substrate or in a package increases due to the high frequency of the filter, and in particular, the impedance becomes capacitive if a filter characteristic having a wide passband is to be produced.

The impedance in the balanced signal terminal should be 200 Ω and should be on the real axis. However, a capacitive impedance is not a substantial problem because a matching circuit is generally provided between an amplifier and a mixer connected thereto. On the other hand, the impedance in the unbalanced signal terminal should be 50 Ω and should be on the real axis. In this case, a problem arises if the impedance is capacitive because an impedance-matching external device cannot be provided in many cases.

### SUMMARY OF THE INVENTION

To overcome the above-described problems, preferred embodiments of the present invention provide a surface acoustic wave device having an unbalanced-to-balanced transformer function, in which a reactance element is not added to an unbalanced signal terminal, the VSWR and deviation in a passband are greatly improved, and the impedance of a balanced signal terminal is four times that of the unbalanced signal terminal, and also provide a communication apparatus including the same.

A surface acoustic wave device according to a preferred embodiment of the present invention includes two surface acoustic wave filters. Each of the two surface acoustic wave filters includes an odd number of at least three IDTs which are arranged in the propagation direction of a surface acoustic wave on a piezoelectric substrate. The IDTs include an IDT for input and an IDT for output which are alternately arranged. The phase of an output signal relative to an input signal in one of the two surface acoustic wave filters is inverted by about 180° with respect to the phase of the other surface acoustic wave filter such that an unbalanced-to-balanced transformer function is obtained. When the number of the IDTs is indicated by N, IDS which are (N−1)/2+1 in number are connected to an unbalanced signal terminal, and IDTs which are (N−1)/2 in number in each of the surface acoustic wave filters are connected to a balanced signal terminal in each of the surface acoustic wave filters. The total number of electrode fingers of the IDTs in each surface acoustic wave filter is at least 71. When the total number of electrode fingers of the IDTs connected to the unbalanced signal terminal is indicated by N1 in each surface acoustic wave filter, and the total number of electrode fingers of the IDT connected to the balanced signal terminal is indicated by N2 in each surface acoustic wave filter, the expression N1>N2 is satisfied.

In this configuration, the surface acoustic wave device preferably includes two surface acoustic wave filters. Each of the two surface acoustic wave filters preferably includes an odd number of at least three IDTs which are arranged in the propagation direction of a surface acoustic wave on a piezoelectric substrate. The IDTs include an IDT for input and an IDT for output which are alternately arranged. The phase of an output signal relative to an input signal in one of the two surface acoustic wave filters is inverted by about 180° with respect to the phase in the other surface acoustic wave filter. When the number of the IDTs is indicated by N, IDTs which are (N−1)/2+1 in number are connected to an unbalanced signal terminal and IDTs which are (N−1)/2 in number are connected to a balanced signal terminal in each surface acoustic wave filter. The total number of electrode fingers of the IDTs in each surface acoustic wave filter is at least 71. When the total number of electrode fingers of the IDTs connected to the unbalanced signal terminal is indicated by N1 and the total number of electrode fingers of the IDT connected to the balanced signal terminal is indicated by N2 in each surface acoustic wave filter, the expression N1>N2 is satisfied.

With this configuration, the impedance of the unbalanced signal terminal is close to the real axis. Accordingly, a surface acoustic wave device having an unbalanced-to-balanced transformer function, in which the VSWR and the deviation in a passband are greatly improved and the impedance of the balanced signal terminal is four times that of the unbalanced signal terminal, is obtained.

Preferably, the surface acoustic wave filter is a longitudinally-coupled resonator type surface acoustic wave filter including three IDTs. With this arrangement, the number of wirings on the piezoelectric substrate (chip) is reduced such that the pattern layout is simplified.

The ratio of a passband width to a center frequency is preferably about 4.3% or more. Accordingly, more preferable VSWR is obtained.

Preferably, the direction of the IDT connected to the unbalanced signal terminal in one of the two surface acoustic wave filters is inverted in the interdigital width direction with respect to the IDT connected to the unbalanced signal terminal in the other surface acoustic wave filter. With this arrangement, the phase of an output signal to an input signal in one of the surface acoustic wave filters can be inverted by about 180° with respect to the phase in the other surface acoustic wave filter, without deteriorating the balance between the balanced signal terminals and the insertion loss in the passband.

Preferably, at least one surface acoustic wave resonator is connected to the surface acoustic wave filter in series, in parallel, or in both in series and parallel. With this arrangement, the impedance in the passband in the input side is close to the real axis, and thus, the surface acoustic wave device, in which a range of variation in VSWR due to the manufacturing variations is greatly reduced, is provided.

Preferably, a package for accommodating the piezoelectric substrate is electrically connected to the piezoelectric substrate by using a flip chip method. With this configuration, an inductance component is not added and the impedance becomes capacitive. Accordingly, the surface acoustic wave device accommodated in the package, in which the VSWR and the deviation in the passband are greatly improved, is provided.

A communication apparatus according to another preferred embodiment of the present invention includes the above-described surface acoustic wave device in order to solve the above-described problems. By using the surface acoustic wave device having improved VSWR and deviation in the passband, a communication apparatus having improved VSWR and deviation in the passband is provided.

The above and other elements, features, characteristics and advantages of the present invention will become clear from the following description of preferred embodiments taken in conjunction with the accompanying drawings.

### BRIEF DESCRIPTION OF THE DRAWINGS

FIG. 1 is a schematic view showing the configuration of a surface acoustic wave device according to a first preferred embodiment of the present invention;

FIG. 2 is a schematic view showing the configuration of a surface acoustic wave device of a comparative example;

FIG. 3 is a cross-sectional view of the surface acoustic wave device according to the first preferred embodiment of the present invention;

FIG. 4 is a graph showing the frequency-transmission characteristic of the surface acoustic wave device shown in FIG. 1;

FIG. 5 is a graph showing the VSWR in the input side (unbalanced signal terminal side) of the surface acoustic wave device shown in FIG. 1;

FIG. 6 is a graph showing the VSWR in the output side (balanced signal terminal side) of the surface acoustic wave device shown in FIG. 1;

FIG. 7 is a graph showing the frequency-transmission characteristic of the surface acoustic wave device shown in FIG. 2;

FIG. 8 is a graph showing the VSWR in the input side (unbalanced signal terminal side) of the surface acoustic wave device shown in FIG. 2;

FIG. 9 is a graph showing the VSWR in the output side (balanced signal terminal side) of the surface acoustic wave device shown in FIG. 2;

FIG. 10 is a Smith chart showing the reflection characteristic of the surface acoustic wave device shown in FIG. 2;

FIG. 11 is a Smith chart showing the reflection characteristic of the surface acoustic wave device shown in FIG. 1;

FIG. 12 is a graph showing the change in VSWR according to the total number of electrode fingers of the IDTs in the surface acoustic wave device shown in FIG. 1;

FIG. 13 is a graph showing the change in VSWR according to the ratio of the number of electrode fingers of the IDTs in the surface acoustic wave device shown in FIG. 1;

FIG. 14 is a graph showing the change in VSWR according to the specific band in the surface acoustic wave device shown in FIG. 1;

FIG. 15 is a schematic view showing the configuration of a modification of the surface acoustic wave device;

FIG. 16 is a schematic view showing the configuration of a surface acoustic wave device according to a second preferred embodiment of the present invention;

FIG. 17 is a Smith chart showing the reflection characteristic of the surface acoustic wave device shown in FIG. 16;

FIG. 18 is a graph showing the VSWR in the input side (unbalanced signal terminal side) of the surface acoustic wave device shown in FIG. 16;

FIG. 19 is a graph showing the VSWR in the output side (balanced signal terminal side) of the surface acoustic wave device shown in FIG. 16;

FIG. 20 is a block diagram showing a critical portion of a communication apparatus including the surface acoustic wave device according to preferred embodiments of the present invention; and

FIG. 21 is a schematic view showing the configuration of a known surface acoustic wave device.

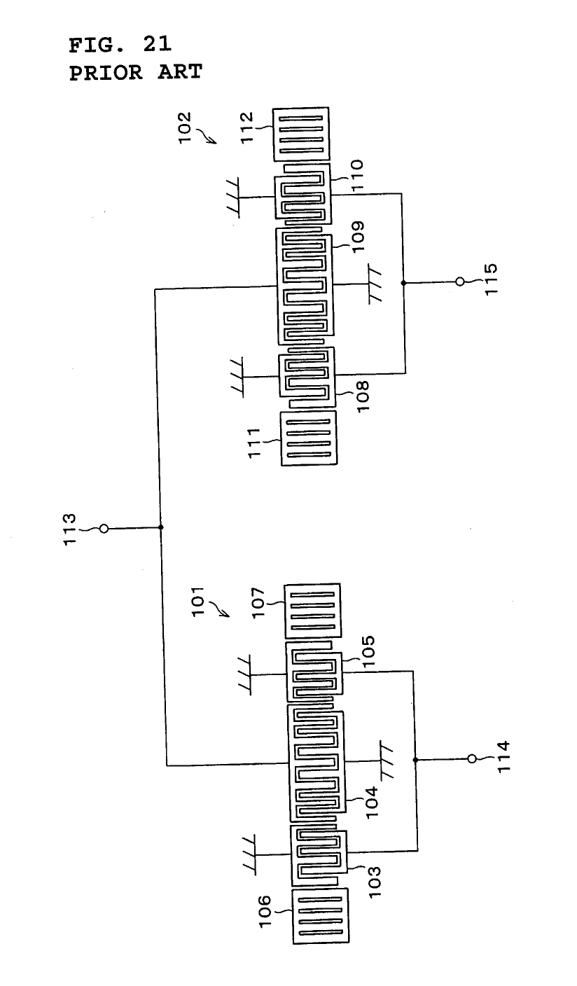

### DETAILED DESCRIPTION OF PREFERRED EMBODIMENTS

First Preferred Embodiment

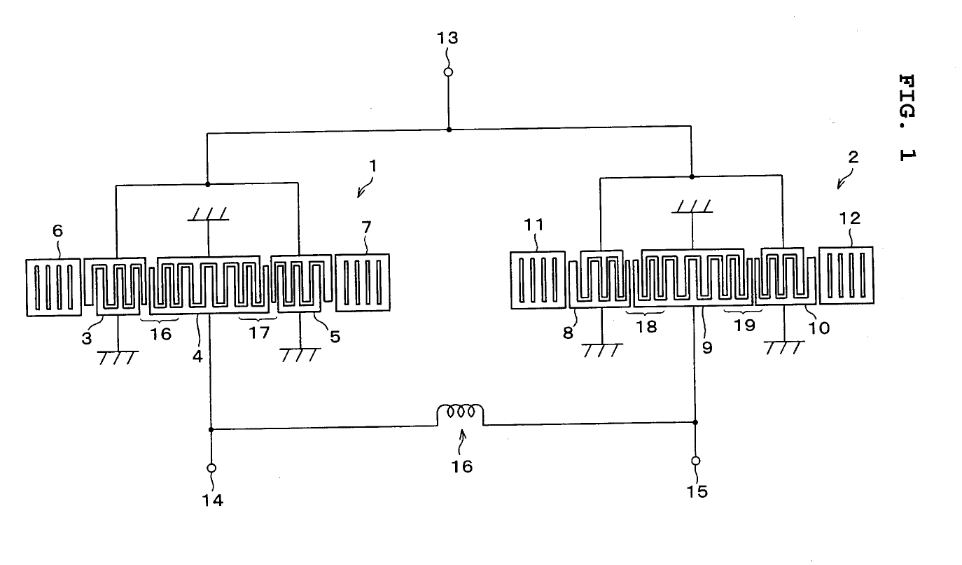

Hereinafter, a first preferred embodiment of the present invention will be described with reference to FIGS. 1 to 15. In this preferred embodiment, a surface acoustic wave device for receiving signals in a digital communication system (DCS) will be described.

FIG. 1 shows the configuration of a critical portion of a surface acoustic wave device of the first preferred embodiment. The surface acoustic wave device includes two longitudinally-coupled resonator type surface acoustic wave filters 1 and 2 defined by Al electrodes, the two filters being provided on a piezoelectric substrate (not shown). In this manner, the surface acoustic wave device according to this preferred embodiment is obtained by using the two longitudinally-coupled resonator type surface acoustic wave filters 1 and 2. In this preferred embodiment, a 40±5° Y-cut X-directional propagation LiTaO₃ substrate is preferably used as the piezoelectric substrate, although other suitable substrates may also be used.

The surface acoustic wave filter 1 includes an interdigital transducer IDT 4 (IDT for output) and IDTs 3 and 5 (IDTs for input) sandwiching the IDT 4. Also, reflectors 6 and 7 are preferably provided so as to sandwich the IDTs 3 to 5. As shown in FIG. 1, the pitch of some electrode fingers in boundary portions between the IDTs 3 and 4 and between the IDTs 4 and 5 is less than the pitch of the other portions of the IDTs, thus defining small-pitch electrode finger portions 16 and 17.

The surface acoustic wave filter 2 includes an IDT 9 (IDT for output) and IDTs 8 and 10 (IDTs for input) sandwiching the IDT 9. Also, reflectors 11 and 12 are arranged so as to sandwich the IDTs 8 to 10. As in the surface acoustic wave filter 1, small-pitch electrode finger portions 18 and 19 are provided in a boundary portion between the IDTs 8 and 9 and a boundary portion between the IDTs 9 and 10, respectively. The direction of the IDTs 8 and 10 of the surface acoustic wave filter 2 is inverted in the interdigital width direction with respect to the IDTs 3 and 5 of the surface acoustic wave filter 1. Accordingly, the phase of an output signal relative to an input signal in the surface acoustic wave filter 2 is inverted by about 180° with respect to the phase of an output signal to an input signal in the surface acoustic wave filter 1.

Also, in this preferred embodiment, the IDTs 3 and 5 sandwiching the central IDT 4 in the surface acoustic wave filter 1 and the IDTs 8 and 10 sandwiching the central IDT 9 in the surface acoustic wave filter 2 are connected to an unbalanced signal terminal 13. Further, the IDTs 4 and 9 of the surface acoustic wave filters 1 and 2 are connected to balanced signal terminals 14 and 15, respectively.

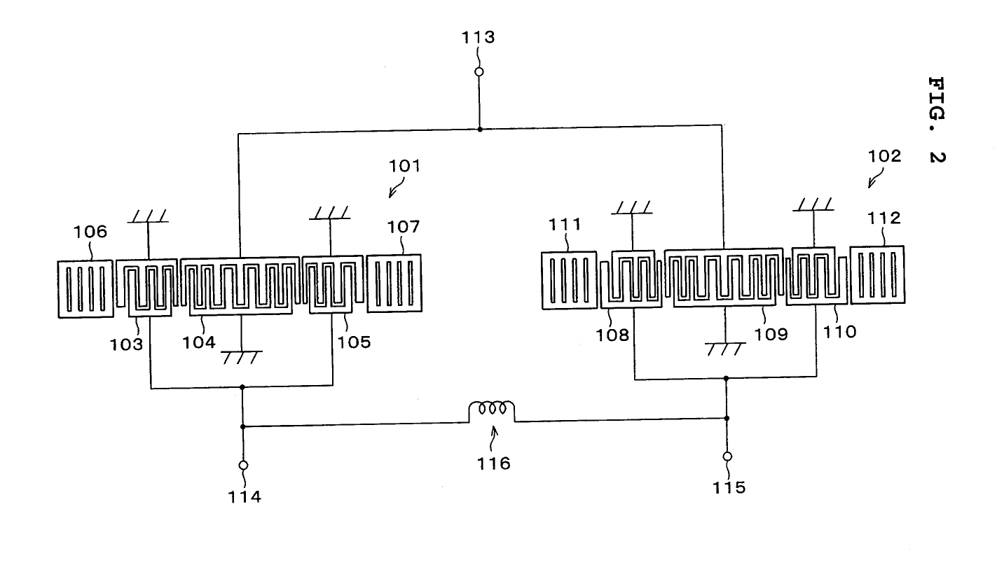

FIG. 2 shows the configuration of a surface acoustic wave device of a comparative example. This configuration is obtained by adding an inductance element 116 between the balanced signal terminals 114 and 115 of a known surface acoustic wave device. That is, in the surface acoustic wave filters 101 and 102, the IDTs 104 and 109 which are positioned at the center of the three IDTs are connected to the unbalanced signal terminal 113, and the IDTs 103 and 105 and the IDTs 108 and 110 sandwiching the central IDT are connected to the balanced signal terminals 114 and 115, respectively.

As described above, in the surface acoustic wave device of the comparative example, the central IDTs 104 and 109 are connected to the unbalanced signal terminal 113, and the IDTs 103 and 105 sandwiching the IDT 104 and the IDTs 108 and 110 sandwiching the IDT 109 are connected to the balanced signal terminals 114 and 115, respectively. On the other hand, in the first preferred embodiment shown in FIG. 1, the IDTs 3 and 5 and the IDTs 8 and 10 are connected to the unbalanced signal terminal 13 and the central IDTs 4 and 9 are connected to the balanced signal terminals 14 and 15, respectively.

In the first preferred embodiment, when the number of IDTs is represented by N, IDTs which are (N−1)/2+1 in number are connected to an unbalanced signal terminal, and IDTs which are (N−1)/2 in number connected to a balanced signal terminal in each of the two surface acoustic wave filters.

Further, an inductance element (reactance) 16 is provided between the balanced signal terminals 14 and 15. In the first preferred embodiment, the value of the inductance element 16 is preferably about 22 nH. Likewise, the value of the inductance element 116 is preferably about 22 nH in the comparative example.

In a recently known surface acoustic wave device including a surface acoustic wave filter having an unbalanced-to-balanced transformer function, a surface acoustic wave filter provided on a piezoelectric substrate is accommodated in a ceramic package and is sealed therein.

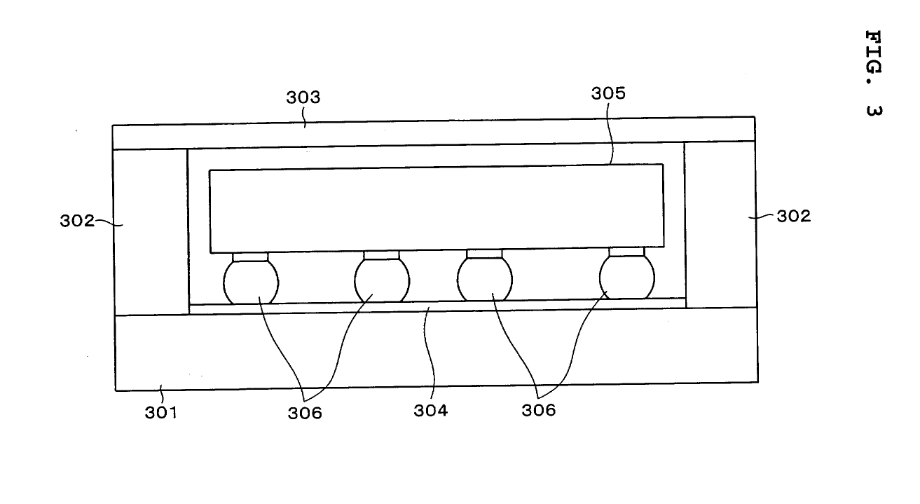

FIG. 3 is a cross-sectional view showing the surface acoustic wave device according to the first preferred embodiment accommodated in a package. The surface acoustic wave device is preferably formed by a flip chip method in which conduction between the package and a piezoelectric substrate 305 on which a surface acoustic wave filter is formed is achieved via bonding bumps 306.

The package has a two-layered configuration and includes a bottom plate 301, side walls 302, and a cap 303. The bottom plate 301 is preferably substantially rectangular, and the side walls 302 are provided at the four peripheral portions of the bottom plate 301, respectively. The cap 303 covers an opening formed by the side walls 302. A die attach portion 304 is formed on the upper surface (inner surface) of the bottom plate 301 such that the package is electrically connected with the piezoelectric substrate 305. The piezoelectric substrate 305 is connected to the die attach portion 304 via the bonding bumps 306. Further, although not shown, an external terminal connected via a through-hole to a wiring pattern is provided on the external surface (surface opposite to the inner surface) of the bottom plate 301.

An example of a specific design of the above-described surface acoustic wave filter 1 is as follows.

Herein, the wavelength of the pitch of small-pitch electrode fingers (small-pitch electrode finger portions 16 and 17) is defined as λI2, and the wavelength of the pitch of the other electrode fingers is defined as λI1.

Interdigital width W: about 46.6 λI1

Number of electrode fingers of IDT (in the order of IDT 3, IDT 4, and IDT 5): 25, 33, and 25

IDT wavelength λI1: 2.148 μm, λI2: about 1.942 μm

Reflector wavelength λR: about 2.470 μm

Number of electrode fingers of reflector: 150

IDT-IDT pitch: about 0.500 λI2

IDT-reflector pitch: about 2.170 μm

Duty: about 0.63 (IDT), about 0.57 (reflector)

Thickness of electrode film: about 0.094 λI1

The pitch means the distance between the centers of two adjacent electrode fingers.

An example of a specific design of the above-described surface acoustic wave filter 2 is the same as that of the surface acoustic wave filter 1, except that the direction of the IDTs 8 and 10 is inverted.

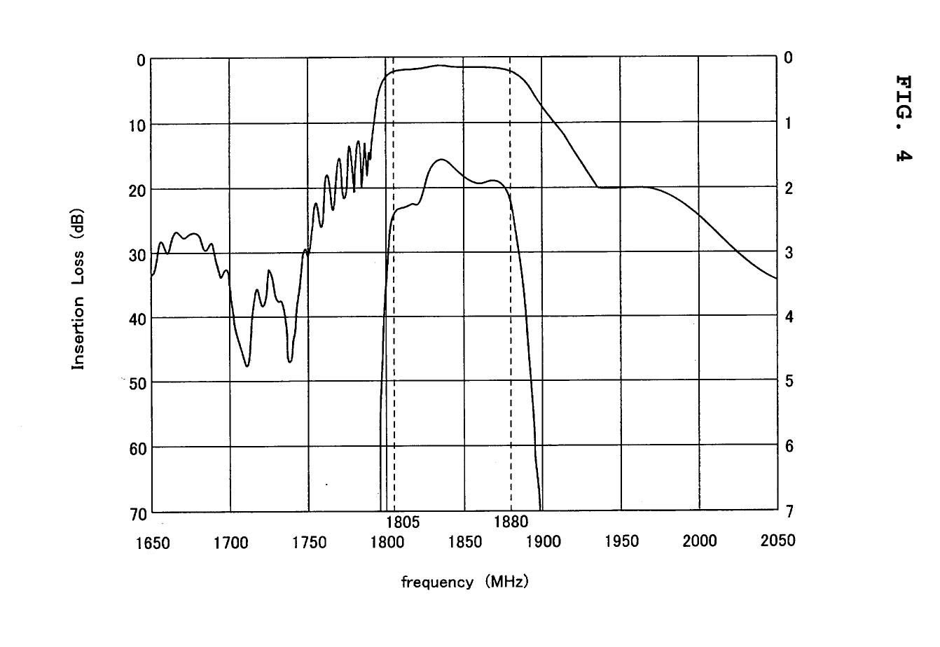

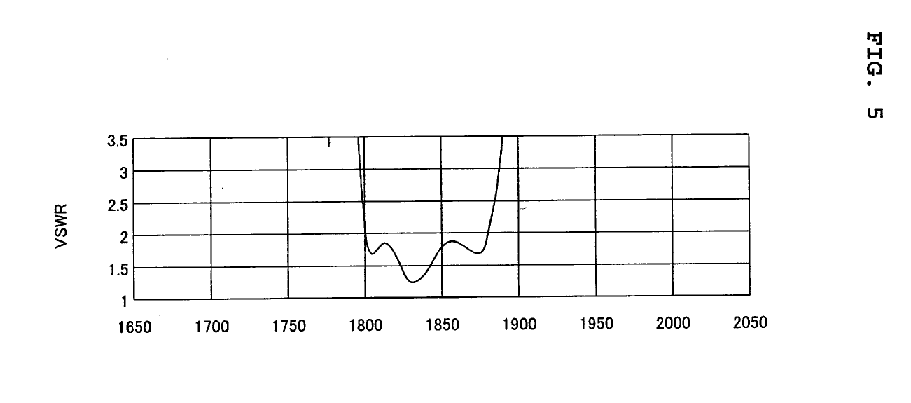

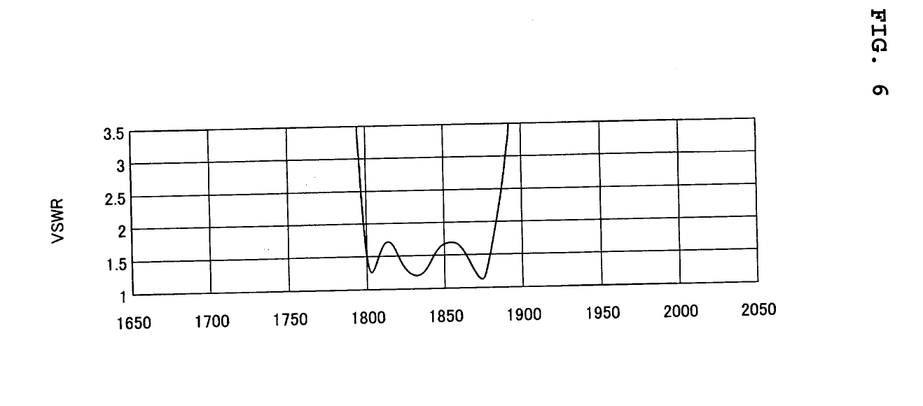

FIG. 4 shows the transmission characteristic versus the frequency, FIG. 5 shows the voltage standing wave ratio (VSWR) of the input side (unbalanced signal terminal side), and FIG. 6 shows the VSWR of the output side (balanced signal terminal side), in the surface acoustic wave device of the first preferred embodiment of the present invention.

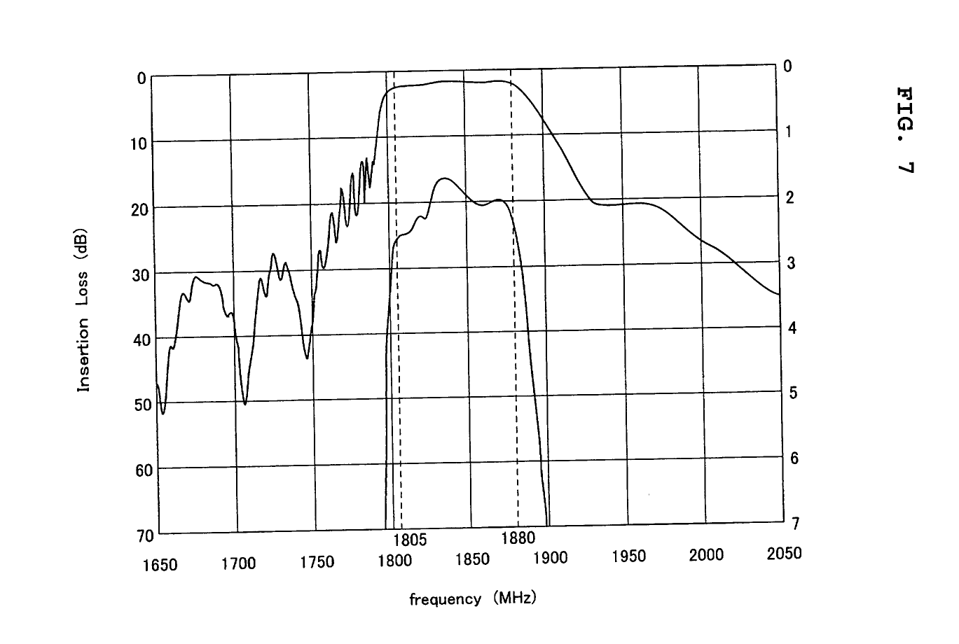

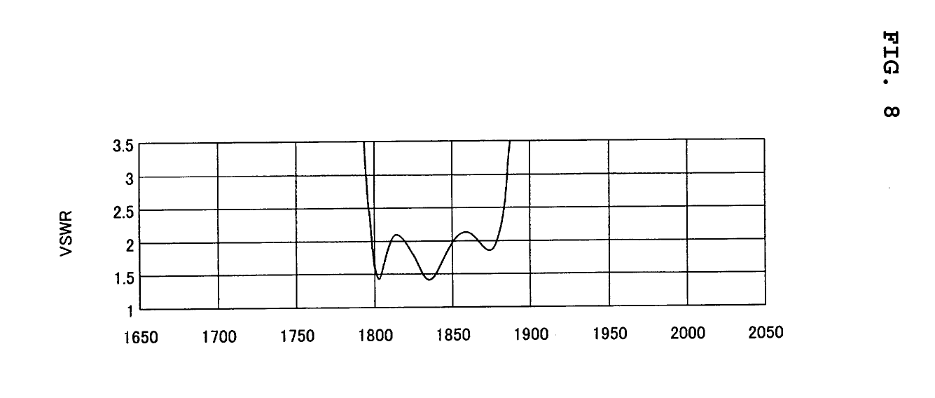

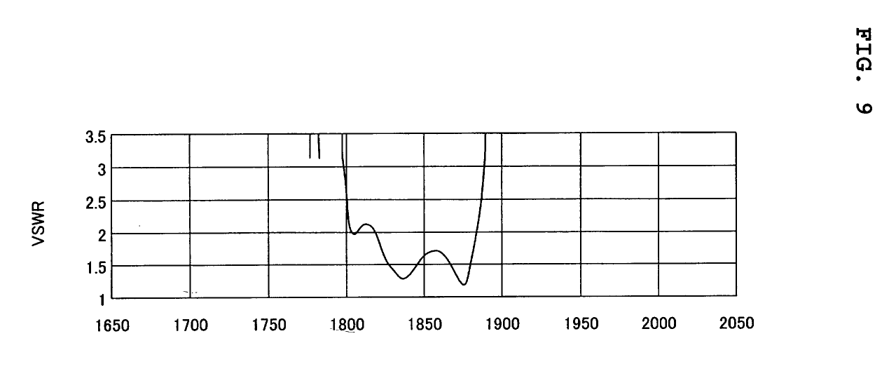

The configuration of each IDT of the comparative example is the same as in the first preferred embodiment, except that the central IDTs 104 and 109 of the surface acoustic wave filters 101 and 102 are connected to the unbalanced signal terminal 113 and the IDTs 103 and 105 and the IDTs 108 and 110 are connected to the balanced signal terminals 114 and 115 respectively, and that the wavelength λI1 is changed to about 2.153 μm and the wavelength λI2 is changed to about 1.935 μm in each IDT so as to adjust the impedance. FIG. 7 shows the transmission characteristic versus the frequency, FIG. 8 shows the VSWR of the input side, and FIG. 9 shows the VSWR of the output side, in the surface acoustic wave device of the comparative example.

In FIGS. 4 and 7, the left scale corresponds to the upper curve, and the right scale corresponds to the lower curve, which is an enlarged curve of the upper curve.

The frequency range of the passband in a DCS reception filter is 1805 MHz to 1880 MHz. The deviation of the passband in this range is about 1.0 dB in the comparative example. In contrast, the deviation in the first preferred embodiment is about 0.7 dB, which is lower than in the comparative example by about 0.3 dB. Also, the maximum insertion loss in the passband is about 2.5 dB in the comparative example, while it is about 2.2 dB in the first preferred embodiment, which is lower than in the comparative example by about 0.3 dB.

Also, in the comparative example, the VSWR is about 2.2 in the input side and in the output side. On the other hand, in the first preferred embodiment, the VSWR is about 1.8 in the input side and about 1.7 in the output side, which are lower than in the comparative example by about 0.4 and 0.5, respectively. That is, in the first preferred embodiment, the deviation and maximum insertion loss in the passband, and the VSWR are greatly improved as compared with the comparative example.

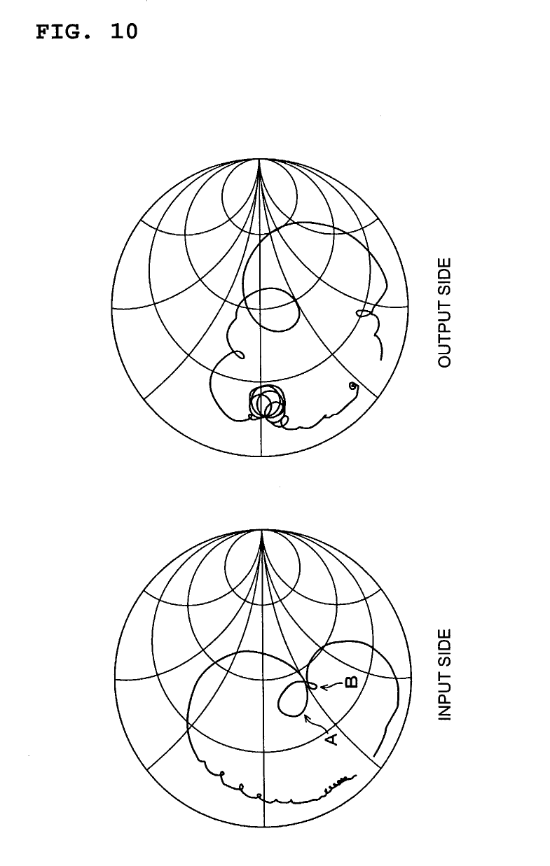

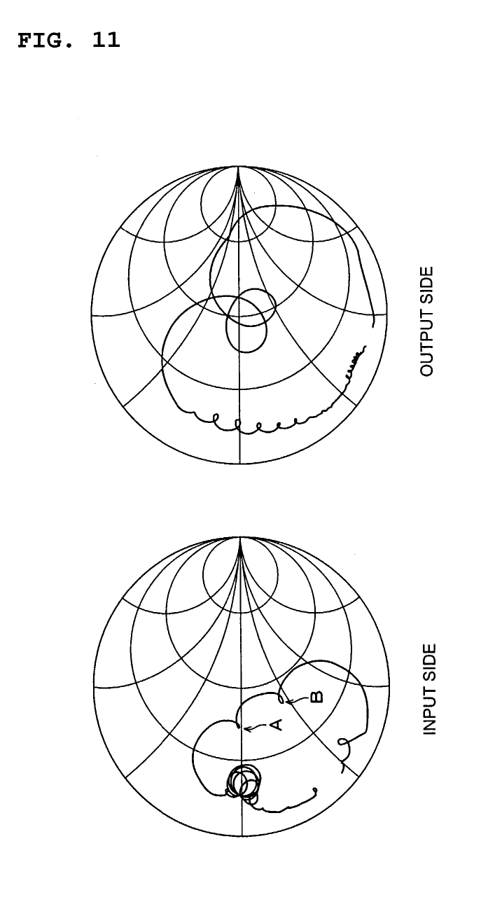

The following are reasons for the advantages of the first preferred embodiment. FIG. 10 is a Smith chart of the reflection characteristic of the comparative example and FIG. 11 is a Smith chart of the reflection characteristic of the first preferred embodiment. As can be seen, the resonances A and B are shifted to the inductive portion in the reflection characteristic in the input side (unbalanced signal terminal side) in the first preferred embodiment, compared to the reflection characteristic in the comparative example. This is because the two IDTs sandwiching the central IDT are connected to the unbalanced signal terminal in the first preferred embodiment, unlike in the comparative example, in which the central IDT is connected to the unbalanced signal terminal.

When a surface acoustic wave device having an unbalanced-to-balanced transformer function is made by using two longitudinally-coupled resonator type surface acoustic wave filters, as in the first preferred embodiment and the comparative example, the IDTs connected to the two balanced signal terminals are connected in series via the ground. Therefore, in a high-frequency filter, such as a DCS filter, the effect of parasitic capacitance is significant, and thus, the impedance in the balanced signal terminal side is primarily caused by capacitance. Accordingly, a reactance element such as an inductance element must be provided between the balanced signal terminals in a surface acoustic wave device having a high frequency and a wide passband width.

Incidentally, if the central IDT is connected to the unbalanced signal terminal side as in the comparative example, the impedance of the unbalanced signal terminal side is capacitive because the number of electrode fingers of the central IDT is less than the sum of the electrode fingers of the two IDTs sandwiching the central IDT. Thus, in the first preferred embodiment, the two IDTs which have more electrode fingers and which sandwich the central IDT are connected to the unbalanced signal terminal such that the impedance of the unbalanced signal terminal is more inductive. Further, an inductance element is provided between the balanced signal terminals such that the impedance is inductive. Accordingly, the deviation in the passband and the VSWR is greatly improved as compared with the comparative example.

Also, in the first preferred embodiment, the design of the surface acoustic wave filter 1 may be different from that of the surface acoustic wave filter 2 in order to increase the balancing between the balanced signal terminals and the attenuation outside the passband. In this case, the same advantages of other preferred embodiments of the present invention are obtained.

In the first preferred embodiment, factors which improve the deviation and VSWR include the configuration in which the two IDTs sandwiching the central IDT are connected to the unbalanced signal terminal. Also, the factors include the total number of electrode fingers of each surface acoustic wave filter, and the ratio between the total number of electrode fingers of the two IDTs sandwiching the central IDT and the total number of electrode fingers of the central IDT, that is, the ratio between the total number of electrode fingers connected to the unbalanced signal terminal and the total number of electrode fingers connected to the balanced signal terminal.

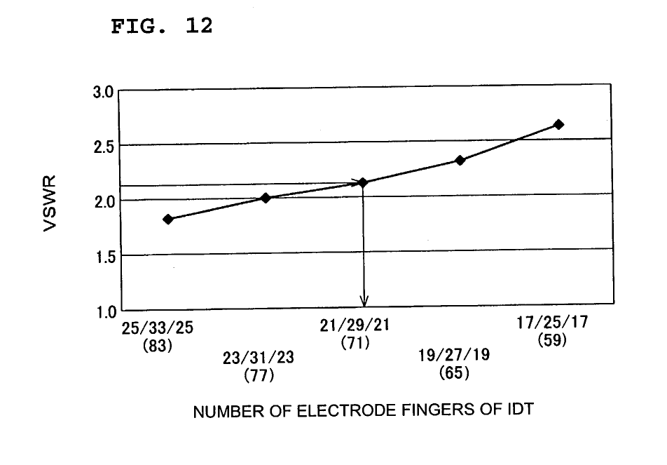

A study has been done in order to determine a desired total number of electrode fingers of the IDTs of each surface acoustic wave filter, in which an improved VSWR, as compared to the surface acoustic wave device of the comparative example, is obtained. FIG. 12 shows the result. The horizontal axis indicates the number of electrode fingers of the IDT 3 or 8, the IDT 4 or 9, and the IDT 5 or 10, and the numbers in parentheses indicate the total number of electrode fingers. In this study, the total number of electrode fingers of the IDTs of each surface acoustic wave filter was gradually decreased, while design parameters, such as the pitch of small-pitch electrode fingers and the IDT-IDT pitch, were adjusted so as to determine the condition which achieves the best VSWR in each number, and the value of VSWR in each case was plotted. As can be seen in FIG. 12, the value of VSWR is at least about 2.2 (the value obtained in the comparative example) when the total number of electrode fingers of the IDTs is less than 71. That is, in order to obtain an improved VSWR as compared to the comparative example, the total number of electrode fingers of the IDTs of each surface acoustic wave filter must be at least 71.

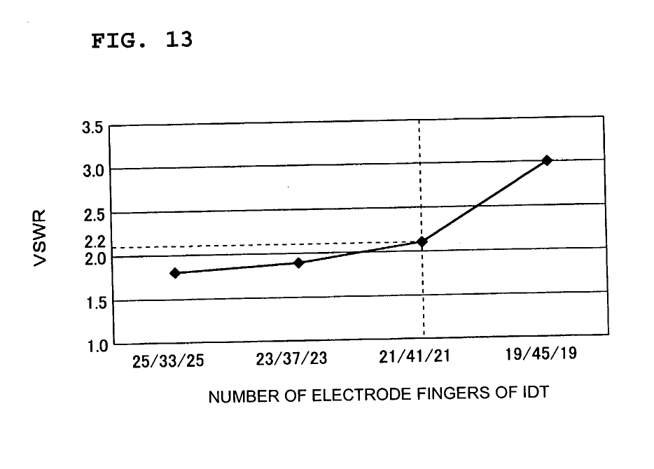

Also, the ratio between the total number of electrode fingers of the IDTs connected to the unbalanced signal terminal and the total number of electrode fingers of the IDT connected to the balanced signal terminal in each surface acoustic wave filter has been studied. FIG. 13 shows the result. Herein, the total number of electrode fingers of the IDTs was 83 in each case. The horizontal axis indicates the number of electrode fingers of the IDT 3 or 8, the IDT 4 or 9, and the IDT 5 or 10. In this study, the number of electrode fingers of the IDT connected to the balanced signal terminal 14 or 15 was gradually increased from 33, while design parameters, such as the pitch of small-pitch electrode fingers and IDT-IDT pitch, were adjusted so as to determine the condition for obtaining the best VSWR in each ratio, and the value of VSWR in each case was plotted. As can be seen in FIG. 13, the VSWR is improved as compared to the comparative example (less than 2.2) when the number of electrode fingers of the IDT 3 or 8, the IDT 4 or 9, and the IDT 5 or 10 is 23, 37, and 23, respectively, that is, when the total number of electrode fingers of the IDTs connected to the unbalanced signal terminal is 46 and the total number of electrode fingers of the IDT connected to the balanced signal terminal is 37. Also, VSWR similar to that in the comparative example is obtained when the number of electrode fingers of each IDT is 21, 41, and 21, respectively, that is, when the total number of electrode fingers of the IDTs connected to the unbalanced signal terminal is 42 and the total number of electrode fingers of the IDT connected to the balanced signal terminal is 41. However, when the total number of electrode fingers connected to the balanced signal terminal is more than 41, the VSWR deteriorates as compared to the comparative example. That is, when the total number of electrode fingers of the IDT connected to the balanced signal terminal is greater than the total number of electrode fingers of the IDTs connected to the unbalanced signal terminal, the VSWR deteriorates. Accordingly, in order to obtain a preferable VSWR, the total number of electrode fingers of the IDTs connected to the unbalanced signal terminal must be greater than the total number of electrode fingers of the IDT connected to the balanced signal terminal.

Preferred embodiments of the present invention are particularly effective in a surface acoustic wave device having a wide passband. A study has been done in order to find the range of passband width of the surface acoustic wave device in which preferred embodiments of the present invention is effective. In the study, design parameters, such as the number of electrode fingers, were changed from the number in the comparative example, and some surface acoustic wave devices, each having a different passband width, were made. Also, a passband width, with which the value of about 1.8 for the VSWR obtained in the first preferred embodiment is obtained in the comparative example, has been studied.

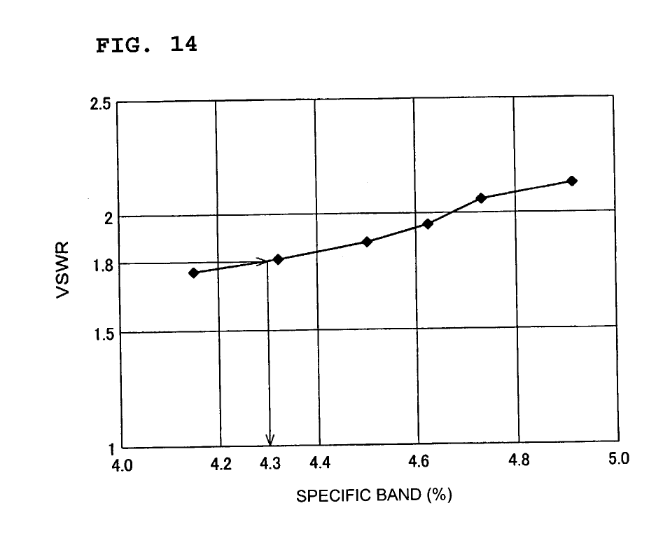

FIG. 14 shows the change in the value of VSWR in accordance with the passband width. The passband width is indicated by a specific band, which is indicated by passband width/center frequency in the level (about 4 dB in the first preferred embodiment) with respect to a through level of the insertion loss required as a filter. As can be seen in FIG. 14, VSWR is about 1.8 or less when the specific band is less than about 4.3%. That is, preferred embodiments of the present invention are effective if the specific band of the surface acoustic wave device is at least about 4.3%.

As described above, in the first preferred embodiment, the two longitudinally-coupled resonator type surface acoustic wave filters are preferably used. Each of the two filters includes three IDTs arranged in the propagation direction of a surface acoustic wave on a piezoelectric substrate. In the three IDTs, an IDT for input and an IDT for output are alternately arranged. Also, the phase of an output signal relative to an input signal in one of the two filters is inverted by about 180° with respect to the phase in the other filter. In each filter, the central IDT is connected to the balanced signal terminal and two IDTs sandwiching the central IDT are connected to the unbalanced signal terminal, and an inductance element is not added to the unbalanced signal terminal. With this configuration, a surface acoustic wave device in which the deviation and maximum insertion loss in the passband and VSWR are greatly improved as compared with the known art is obtained.

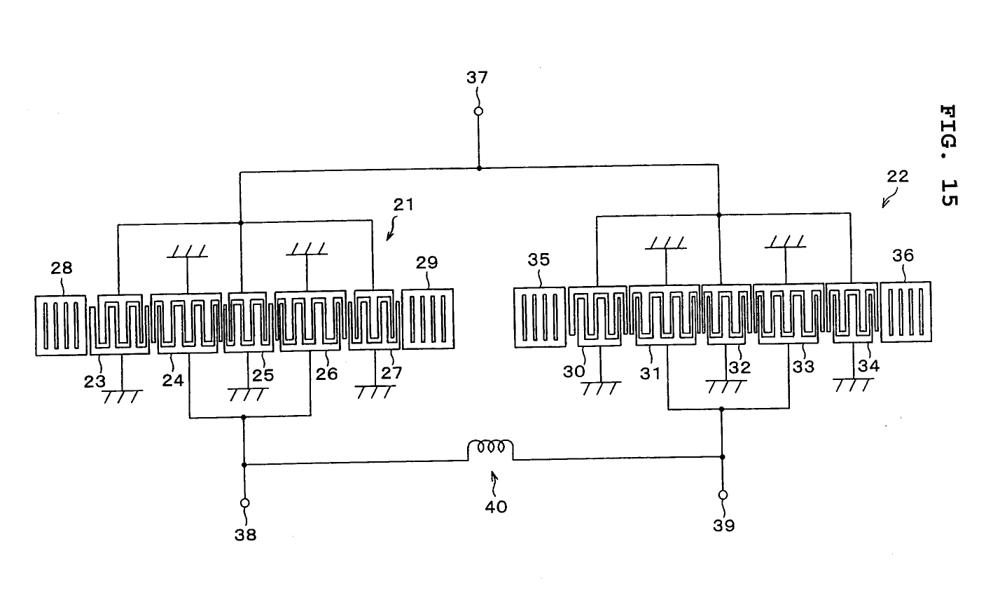

The above-described surface acoustic wave device includes two longitudinally-coupled resonator type surface acoustic wave filters, each having three IDTs. However, as shown in FIG. 15, the surface acoustic wave device may include a longitudinally-coupled resonator type surface acoustic wave filter 21 having five IDTs 23 to 27 and a longitudinally-coupled resonator type surface acoustic wave filter 22 having five IDTs 30 to 34.

The number of IDTs may be 5 or more as long as the number is odd. In that case, when the number of IDTs is represented by N, IDTs having a number equal to (N−1)/2+1 are connected to the unbalanced signal terminal, and IDTs having a number equal to (N−1)/2 are connected to the balanced signal terminal for each of the two surface acoustic wave filters. Further, an inductance element is provided between the two balanced signal terminals. Accordingly, a surface acoustic wave device in which the deviation in a passband and VSWR are greatly improved is obtained. However, if a multi-electrode surface acoustic wave filter is used, the pattern layout of wiring on a piezoelectric substrate (chip) is disadvantageously complicated. Therefore, it is preferable to use the above-described longitudinally-coupled resonator type surface acoustic wave filter including three IDTs.

In the first preferred embodiment, the direction of the IDTs 8 and 10 is inverted in the interdigital width direction with respect to the IDTs 3 and 5 so that the phase of an output signal to an input signal is inverted by about 180°. However, the phase may be inverted by about 180° in another way. For example, the direction of the IDT 9 may be inverted in the interdigital width direction with respect to the IDT 4 such that the phase is inverted by about 180°. Alternatively, the IDT-IDT pitch in one of the two longitudinally-coupled resonator type surface acoustic wave filters may differ by about 0.5 λI1 as compared to the IDT-IDT pitch in the other longitudinally-coupled resonator type surface acoustic wave filter such that the phase is inverted by about 180°.

However, if the direction of the IDT connected to the balanced signal terminal is inverted, the balancing between the balanced signal terminals deteriorates. Also, if the IDT-IDT pitch is changed by about 0.5 λI1, the surface acoustic wave in the surface acoustic wave filter having the increased pitch is transformed to a bulk wave and increased loss is produced. As a result, the insertion loss in the passband deteriorates. Accordingly, it is preferable to invert the interdigital width direction the direction of IDTs connected to the unbalanced signal terminal so as to inverse the phase by about 180°.

In the first preferred embodiment, a flip chip method is used in which the package is electrically connected to the piezoelectric substrate via bonding bumps. If the flip chip method is not used and the package is electrically connected to the piezoelectric substrate via a wire bond, the impedance is likely to be inductive due to the inductance component of the wire. In contrast, in the flip chip method, the impedance is likely to be capacitive because the inductance component of the wire is eliminated. Therefore, great advantages are obtained by using the flip chip method.

In the first preferred embodiment, the inductance element is connected between the two balanced signal terminals. Alternatively, a reactance element other than that of the first preferred embodiment, such as a capacitance element, may be connected in series to each of the two balanced signal terminals. Further, the inductance element need not be connected if matching between the balanced signal terminals is not necessary.

Further, in the first preferred embodiment, a 40±5° Y-cut X-directional propagation LiTaO₃ substrate is preferably used. However, as can be understood from the principle for obtaining the effects, the same effects can be obtained if a 64-74° Y-cut X-directional propagation LiTaO₃ substrate or a 41° Y-cut X-directional LiTaO₃ substrate is used.

Second Preferred Embodiment

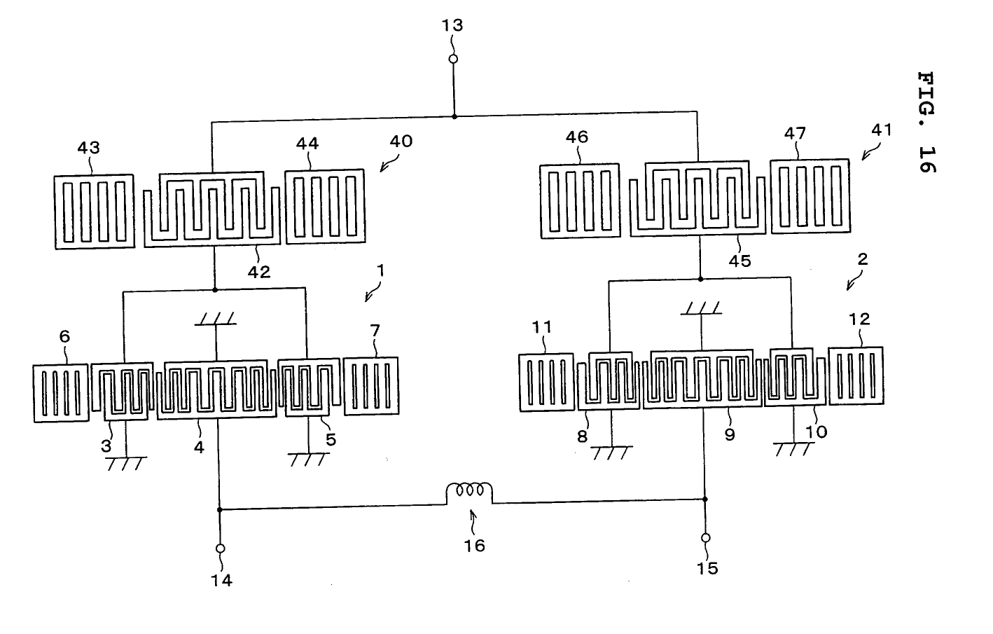

Hereinafter, a second preferred embodiment of the present invention will be described with reference to FIGS. 16 to 20. In the second preferred embodiment, elements having the same functions as those in the first preferred embodiment are denoted by the same reference numerals, and the corresponding description is omitted.

FIG. 16 shows the configuration of a surface acoustic wave device according to the second preferred embodiment of the present invention. In the second preferred embodiment, surface acoustic wave resonators 40 and 41 are added to the configuration of the first preferred embodiment. The resonator 40 is provided between the unbalanced signal terminal 13 and the IDTs 3 and 5, and the resonator 41 is provided between the unbalanced signal terminal 13 and the IDTs 8 and 10. That is, the surface acoustic wave resonators 40 and 41 are connected in series between the unbalanced signal terminal 13 and the longitudinally-coupled resonator type surface acoustic wave filters 1 and 2, respectively. The longitudinally-coupled resonator type surface acoustic wave filters 1 and 2 preferably have the same configuration as in the first preferred embodiment. Also, in the surface acoustic wave resonators 40 and 41, IDTs 42 and 45 are sandwiched by reflectors 43 and 44 and reflectors 46 and 47, respectively, in the propagation direction of a surface acoustic wave.

The specific design of each of the surface acoustic wave resonators 40 and 41 is preferably as follows.

Interdigital width W: about 13.8 λ

Number of electrode fingers of IDT: 241

Wavelength λ: about 2.167 μm (both in IDT and reflector)

Number of electrode fingers of reflector: 30

IDT-reflector pitch: about 0.500 λ

Duty: about 0.60

Thickness of electrode film: about 0.095 λ

The pitch means the distance between the centers of two adjacent electrode fingers.

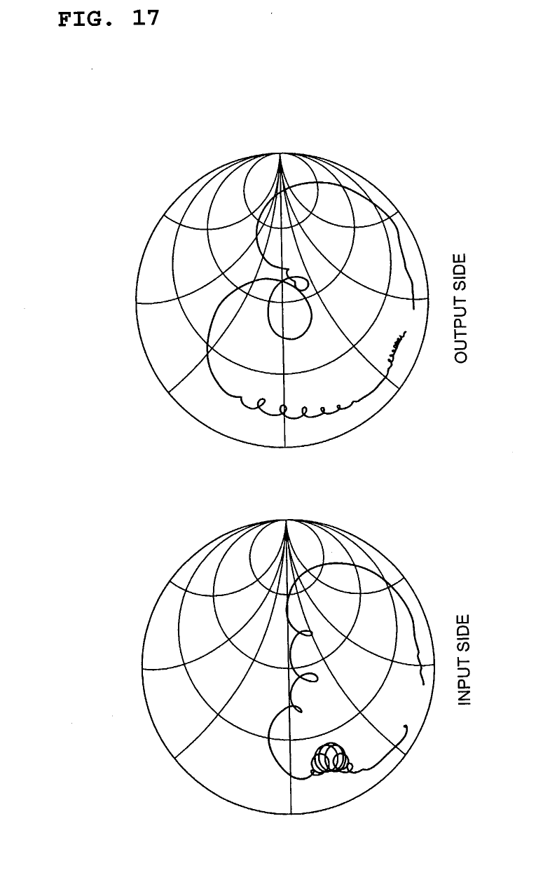

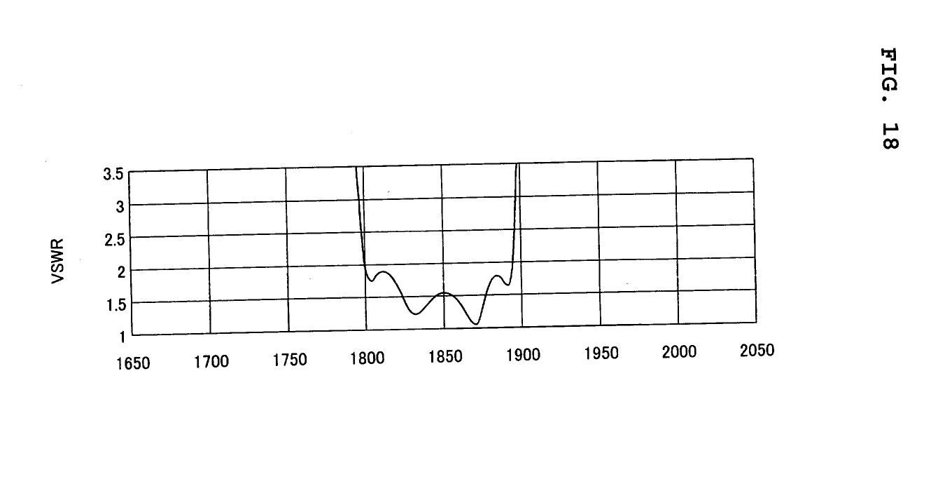

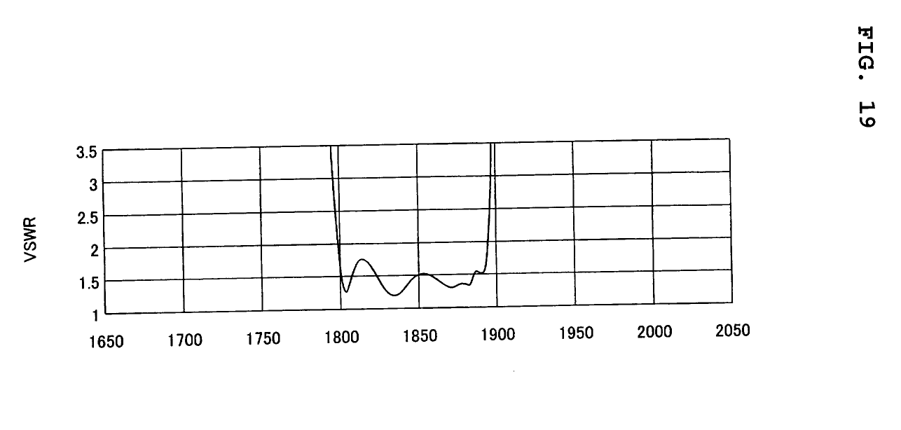

FIG. 17 is a Smith chart of the reflection characteristic of the surface acoustic wave device of the second preferred embodiment, FIG. 18 shows the VSWR in the input side, and FIG. 19 shows the VSWR in the output side. Since the surface acoustic wave resonators 40 and 41 are provided between the unbalanced signal terminal 13 and the IDTs 3 and 5 and between the unbalanced signal terminal 13 and the IDTs 8 and 10, respectively, the impedance in the passband in the input side is on the real axis as compared to the first preferred embodiment. Therefore, the surface acoustic wave device, in which a range of variation in VSWR due to the variation of manufacture is greatly reduced, is obtained. Also, since the surface acoustic wave resonators 40 and 41 are connected in series, the surface acoustic wave device, in which the attenuation in a high-frequency side from the passband is greatly increased, is obtained.

In the second preferred embodiment, the surface acoustic wave resonators 40 and 41 are connected in series between the surface acoustic wave filters 1 and 2 and the unbalanced signal terminal 13. However, the advantages of preferred embodiments of the present invention are also obtained if the surface acoustic wave resonators are connected in parallel or in both series and parallel.

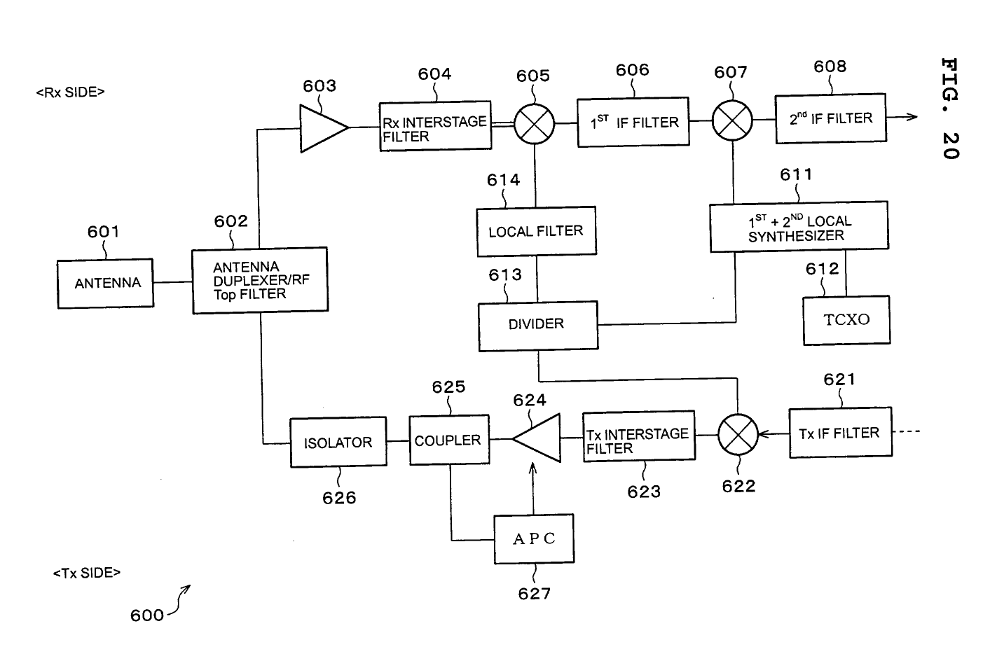

Next, a communication apparatus including the above described surface acoustic wave device will be described with reference to FIG. 20. A communication apparatus 600 includes a receiver side (Rx side) for receiving signals and a transmitter side (Tx side) for transmitting signals. The Rx side includes an antenna 601, an antenna duplexer/RF Top filter 602, an amplifier 603, an Rx interstage filter 604, a mixer 605, a first IF filter 606, a mixer 607, a second IF filter 608, a first+second local synthesizer 611, a temperature compensated crystal oscillator (TCXO) 612, a divider 613, and a local filter 614.

Preferably, each balanced signal is transmitted from the Rx interstage filter 604 to the mixer 605 to ensure balance, as shown by double lines in FIG. 20.

The Tx side includes the above-mentioned antenna 601 and the antenna duplexer/RF Top filter 602, which are shared with the Rx side, and also includes a Tx IF filter 621, a mixer 622, a Tx interstage filter 623, an amplifier 624, a coupler 625, an isolator 626, and an automatic power control (APC) 627.

As the Rx interstage filter 604, the above described surface acoustic wave device according to the first and second preferred embodiments is preferably used.

The surface acoustic wave device according to preferred embodiments of the present invention has a filter function and an unbalanced-to-balanced transformer function. Further, the device has an outstanding characteristic in that the VSWR and the deviation in the passband width are greatly improved. Accordingly, the communication apparatus including the above-described surface acoustic wave device has an increased transmission characteristic.

While preferred embodiments of the invention have been described above, it is to be understood that variations and modifications will be apparent to those skilled in the art without departing the scope and spirit of the invention. The scope of the invention, therefore, is to be determined solely by the following claims.

What is claimed is:

1. A surface acoustic wave device comprising:
a piezoelectric substrate;
at least two surface acoustic wave filters;
wherein each of the at least two surface acoustic wave filters includes an odd number of at least three IDTs which are arranged in the propagation direction of a surface acoustic wave on the piezoelectric substrate, and the at least three IDTs include an IDT for input and an IDT for output which are alternately arranged;
the phase of an output signal relative to an input signal in one of the at least two surface acoustic wave filters is inverted by about 180° with respect to the phase in the other of the at least two surface acoustic wave filters such that an unbalanced-to-balanced transformer function is obtained;
when the number of said IDTs is indicated by N, IDTs having a number equal to (N−1)/2+1 are connected to an unbalanced signal terminal and IDTs having a number equal to (N−1)/2 in each of the surface acoustic wave filters are connected to a balanced signal terminal in each of the surface acoustic wave filters;
the total number of electrode fingers of the IDTs in each of the at least two surface acoustic wave filters is at least 71; and
when the total number of electrode fingers of the IDTs connected to the unbalanced signal terminal is indicated by N1 in each of the at least two surface acoustic wave filters, and the total number of electrode fingers of the IDT connected to the balanced signal terminal is indicated by N2 in each of the at least two surface acoustic wave filters, an expression N1>N2 is satisfied.

2. The surface acoustic wave device according to claim 1, wherein each of the at least two surface acoustic wave filters is a longitudinally-coupled resonator type surface acoustic wave filter including three IDTs.

3. The surface acoustic wave device according to claim 1, wherein the ratio of a passband width to a center frequency of the surface acoustic wave device is at least about 4.3%.

4. The surface acoustic wave device according to claim 1, wherein a direction of the IDT connected to the unbalanced signal terminal in one of the at least two surface acoustic wave filters is inverted in the interdigital width direction with respect to the IDT connected to the unbalanced signal terminal in the other of the at least two surface acoustic wave filters.

5. The surface acoustic wave device according to claim 1, wherein at least one surface acoustic wave resonator is connected to at least one of the at least two surface acoustic wave filters in series, in parallel, or in both series and parallel.

6. The surface acoustic wave device according to claim 1, wherein a package for accommodating the piezoelectric substrate is electrically connected to the piezoelectric substrate by using a flip chip method by a flip-chip bonded connection.

7. A communication apparatus comprising the surface acoustic wave device according to claim 1.

8. A surface acoustic wave device comprising:
a piezoelectric substrate;
at least two surface acoustic wave filters;
wherein each of the at least two surface acoustic wave filters includes an odd number of at least three IDTs which are arranged in the propagation direction of a surface acoustic wave on the piezoelectric substrate, and the at least three IDTs include an IDT for input and an IDT for output which are alternately arranged;
the phase of an output signal relative to an input signal in one of the at least two surface acoustic wave filters is inverted by about 180° with respect to the phase in the other of the at least two surface acoustic wave filters such that an unbalanced-to-balanced transformer function is obtained;
when the number of said IDTs is indicated by N, IDTs having a number equal to (N−1)/2+1 are connected to an unbalanced signal terminal and IDTs having a number equal to (N−1)/2 in each of the at least two surface acoustic wave filters are connected to a balanced signal terminal in each of the at least two surface acoustic wave filters; and
when the total number of electrode fingers of the IDTs connected to the unbalanced signal terminal is indicated by N1 in each of the at least two surface acoustic wave filters, and the total number of electrode fingers of the IDT connected to the balanced signal terminal is indicated by N2 in each of the at least two surface acoustic wave filters, an expression N1>N2 is satisfied.

9. The surface acoustic wave device according to claim 8, wherein the total number of electrode fingers of the IDTs in each of the at least two surface acoustic wave filters is at least 71.

10. The surface acoustic wave device according to claim 8, wherein each of the at least two surface acoustic wave filters is a longitudinally-coupled resonator type surface acoustic wave filter including three IDTs.

11. The surface acoustic wave device according to claim 8, wherein the ratio of a passband width to a center frequency of the surface acoustic wave device is at least about 4.3%.

12. The surface acoustic wave device according to claim 8, wherein a direction of the IDT connected to the unbalanced signal terminal in one of the at least two surface acoustic wave filters is inverted in the interdigital width direction with respect to the IDT connected to the unbalanced signal terminal in the other of the at least two surface acoustic wave filters.

13. The surface acoustic wave device according to claim 8, wherein at least one surface acoustic wave resonator is connected to at least one of the at least two surface acoustic wave filters in series, in parallel, or in both series and parallel.

14. The surface acoustic wave device according to claim 8, wherein a package for accommodating the piezoelectric substrate is electrically connected to the piezoelectric substrate by using a flip chip method.

15. A communication apparatus comprising the surface acoustic wave device according to claim 8.

16. A surface acoustic wave device comprising:
a piezoelectric substrate;
at least two surface acoustic wave filters;
wherein each of the at least two surface acoustic wave filters includes an odd number of at least three IDTs which are arranged in the propagation direction of a surface acoustic wave on a piezoelectric substrate, and the at least three IDTs include an IDT for input and an IDT for output which are alternately arranged;
the phase of an output signal to an input signal in one of the at least two surface acoustic wave filters is inverted by about 180° with respect to the phase in the other of the at least two surface acoustic wave filters such that an unbalanced-to-balanced transformer function is obtained;
the total number of electrode fingers of the IDTs in each surface acoustic wave filter is at least 71; and
when the total number of electrode fingers of the IDTs connected to the unbalanced signal terminal is indicated by N1 in each of the at least two surface acoustic wave filters, and the total number of electrode fingers of the IDT connected to the balanced signal terminal is indicated by N2 in each of the at least two surface acoustic wave filters, an expression N1>N2 is satisfied.

17. The surface acoustic wave device according to claim 16, wherein when the number of said IDTs is indicated by N, IDTs having a number equal to (N−1)/2+1 are connected to an unbalanced signal terminal and IDTs having a number equal to (N−1)/2 in each of the surface acoustic wave filters are connected to a balanced signal terminal in each of the surface acoustic wave filters.

18. The surface acoustic wave device according to claim 16, wherein each of the at least two surface acoustic wave filters is a longitudinally-coupled resonator type surface acoustic wave filter including three IDTs.

19. The surface acoustic wave device according to claim 16, wherein the ratio of a passband width to a center frequency of the surface acoustic wave device is at least about 4.3%.

20. The surface acoustic wave device according to claim 16, wherein a direction of the IDT connected to the unbalanced signal terminal in one of the at least two surface acoustic wave filters is inverted in the interdigital width direction with respect to the IDT connected to the unbalanced signal terminal in the other of the at least two surface acoustic wave filters.

21. The surface acoustic wave device according to claim 16, wherein at least one surface acoustic wave resonator is connected to the at least one of the at least two surface acoustic wave filters in series, in parallel, or in both series and parallel.

22. The surface acoustic wave device according to claim 16, wherein a package for accommodating the piezoelectric substrate is electrically connected to the piezoelectric substrate by using a flip chip method.

23. A communication apparatus comprising the surface acoustic wave device according to claim 16.
